(19) United States
(12) Patent Application Publication
(10) Pub. No.: US 2007/0289943 A1
(43) Pub. Date: Dec. 20, 2007

(54) Block copolymer mask for defining nanometer-scale structures

(76) Inventors: Jennifer Lu, Milpitas, CA (US); Hui Wang, Palo Alto, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/453,952

(22) Filed: Jun. 14, 2006

(51) Int. Cl. G03F 1/00; C23F 1/00

(52) U.S. Cl. 216/41; 430/5

(57) ABSTRACT

A nanometer-scale mask includes a periodic array of nanometer-scale structural elements comprising an inorganic oxide.

### BACKGROUND OF THE INVENTION

The separation of biomolecules, such as DNA, is typically performed using electrophoresis or liquid chromatography.

When analyzing physically large biomolecules, such as DNA, RNA, proteins, peptides, etc., conventional liquid chromatography has several limitations. One limitation is the difficulty in achieving consistent and reproducible packing density of the physical medium in the column. Another limitation is referred to as a “stagnant mobile phase mass transfer” limitation of the porous physical medium in the column. The stagnant mobile phase mass transfer is the rate at which solute molecules transfer in and out of the stationary phase or the intrabead void volume. Further, conventional liquid chromatography is only useful for certain biomolecules and related solvents in a narrow concentration range and is only effective for separating biomolecules in a limited temperature range.

Another manner of separating biomolecules uses a material with micrometer-scale channels as the liquid chromatography packing material. However, to effectively separate materials with similar molecular weight, it is also desirable to have small channels, at the nanometer scale. Unfortunately, forming such nanometer-scale structures is difficult.

Therefore, it would be desirable to have a way to efficiently and reliably produce a nanometer-scale structure.

### SUMMARY OF THE INVENTION

In an embodiment, a nanometer-scale mask comprises a periodic array of nanometer-scale structural elements comprising an inorganic oxide.

The invention also provides a method for forming a mask on a substrate. The method comprises forming a self-assembled block copolymer on the substrate, the self-assembled block copolymer comprising a matrix and a periodic array of microdomains embedded in the matrix, the microdomains comprising an inorganic species having a non-volatile oxide. The method also comprises oxidizing the self-assembled block copolymer to form as the mask a periodic array of nanometer-scale structural elements comprising the non-volatile oxide.

The mask allows the fabrication of extremely fine-pitch nanometer-scale structures having high aspect ratios that can be used to fabricate a biomolecule separation medium.

### BRIEF DESCRIPTION OF THE DRAWINGS

The invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIGS. 1A through 1C are schematic diagrams showing various stages of an embodiment of a process for forming a nanometer-scale mask.

FIG. 2 is a schematic diagram showing a process for using the mask of FIG. 1C to define a nanometer-scale structure in a substrate.

FIG. 3 is a schematic plan view of the mask with nanometer-scale features shown in FIG. 1C.

FIGS. 4A through 4E are schematic diagrams showing an alternative embodiment of a process for creating a mask using the self-assembled block copolymer of FIGS. 1A through 1C and using the mask to etch a substrate.

FIG. 5A is a schematic diagram showing two vector polymer films applied to respective regions of the surface of a substrate.

FIG. 5B is a schematic diagram showing a profile view of the two vector polymer films applied to respective regions of the surface of a substrate after annealing.

FIG. 5C shows the block copolymers and of FIG. 5B after oxidation.

FIG. 6 is a schematic diagram showing a plan view of the mask of FIG. 5C.

FIG. 7 is a flowchart showing a method of forming a nanometer-scale mask in accordance with an embodiment of the invention.

FIG. 8 is a flowchart showing a method of defining a nanometer-scale structure in accordance with an embodiment of the invention.

FIG. 9 is a flowchart showing an alternative method of creating a nanometer-scale structure in accordance with another embodiment of the invention.

FIGS. 10A through 10D are schematic diagrams showing plan views of a biomolecule separation medium created using the block copolymer mask described above.

### DETAILED DESCRIPTION OF THE INVENTION

A block-copolymer mask for forming nanometer-scale structures will be described below in the context of forming a structure for performing biomolecule separation. However, the block-copolymer mask for forming nanometer-scale structures can be used in other applications in which a nanometer-scale structure is needed.

Prior to describing embodiments of the invention, a description of a block copolymer is provided to aid in the understanding of the embodiments to be described below. The term “polymer” refers to a chemical compound formed by polymerization and consisting essentially of repeating structural units. The basic chemical “units” that are used in building a polymer are referred to as “repeat units.” A polymer may have a large number of repeat units or a polymer may have relatively few repeat units, in which case the polymer is often referred to as an “oligomer.”

When a polymer is made by linking only one type of repeat unit together, it is referred to as a “homopolymer.” When two (or more) different types of repeat units are joined in the same polymer chain, the polymer is called a “copolymer.” In copolymers, the different types of repeat units can be joined together in different arrangements. For instance, two repeat units may be arranged in an alternating fashion, in which case the polymer is referred to as an “alternating copolymer.” As another example, in a “random copolymer,” the two repeat units may follow in any order. Further, in a “block copolymer,” all of one type of repeat unit are grouped together, and all of the other type of repeat unit are grouped together. Thus, a block copolymer can generally be thought of as two homopolymers joined in tandem. A block copolymer can include two or more units of a polymer chain joined together by covalent bonds. A “diblock copolymer” is a block copolymer that contains only two units joined together by a covalent bond. A “triblock copolymer” is a block copolymer that contains only three units joined together by covalent bonds.

A polymer that may be processed to deliver an inorganic payload on the surface of a substrate is referred to herein as a “vector polymer.” As described further below, such a vector polymer self-assembles into a desired structure for controlling the size and/or distribution of nanoparticles produced by the inorganic payload carried by such vector polymer. Thus, the vector polymer self-assembles into a desired structure of inorganic material-containing domains. The non-payload (e.g., organic) components of the vector polymer can then be removed, resulting in the inorganic nanoparticles remaining on the substrate with their size and/or distribution controlled by the vector polymer's self-assembly. While in certain exemplary embodiments described herein a diblock copolymer (A-B) is used as a vector polymer for carrying an inorganic payload, the scope of the present invention is not so limited. Rather, any polymer (e.g., triblock polymer, etc.) that is capable of self-assembly and in which at least one repeat unit thereof includes an inorganic payload may be utilized in accordance with the concepts presented herein. For instance, in certain embodiments a block copolymer A-B-A may be used. Further, in certain embodiments, a mixture of block copolymers (e.g., diblock copolymers) and homopolymers or a miscible blend of two homopolymers (A) and (B) is used to form a film containing self-assembling polymers. As an example, a diblock polymer and two homopolymers are used for forming the film containing self-assembling polymers.

Amphiphilic block copolymers are known self-assembly systems in which chemically distinct blocks microphase-separate into the periodic domains. The domains adopt a variety of nanoscale morphologies, such as lamellar, double gyroid, cylindrical, or spherical, depending on the polymer chemistry and molecular weight. Embodiments are described herein in which such amphiphilic block copolymers are used as carriers of inorganic payloads, wherein the self-assembly of the block copolymers into a desired nanoscale morphology results in a controlled arrangement of the inorganic nanoparticles formed from the carried inorganic payloads.

The block that contains the inorganic payload is referred to as a payload-containing block. One or more instances of such a payload-containing block is present in each block polymer. For instance, in certain embodiments, a diblock copolymer has one block that is a payload-containing block and another block that contains no inorganic payload. The block that contains no inorganic payload is referred to as the matrix. As described further below, a block copolymer deposited on the surface of a substrate and subject to annealing will self-assemble into a predetermined structure (i.e., a desired nanoscale morphology). The structure into which the block copolymer self-assembles controls the size and relative spacing of the inorganic nanoparticles formed from the inorganic payload carried by the block copolymer.

Various techniques can be used for forming block copolymers containing an inorganic payload. One exemplary technique involves complexation of an inorganic payload (e.g., atoms of an inorganic species) with a block of a diblock copolymer. For instance, incorporation of an inorganic species, which may be a metal, such as iron, cobalt, and molybdenum, into one block of a diblock copolymer is accomplished by complexation of the atoms of the inorganic species with the pyridine units of polystyrene-b-poly(vinyl pyridine) (PS-b-PVP). Another exemplary technique involves direct synthesis of a payload-containing diblock copolymer. For instance, sequential living polymerization of the nonmetal-containing styrene monomer followed by the inorganic species-containing monomer of ferrocenylethylmethylsilane to form polystyrene-b-poly(ferrocenylethylmethylsilane) (PS-b-PFEMS) is an exemplary technique for direct synthesis of an inorganic species-containing diblock copolymer.

By controlling the volume of each of the blocks (A and B) of the diblock copolymer, the structures into which the diblock copolymer self-assembles during annealing can be controlled. The volume ratio between the blocks of the diblock copolymer determines the morphology, such as lamellar, double gyroid, cylindrical, or spherical, of the microdomains into which the diblock copolymer self-assembles. Additionally, the volumes of the blocks determine the size of the microdomains and the spacing between the microdomains in the matrix after the self-assembly process. Accordingly, a volume ratio between the blocks of a diblock copolymer is first determined based on the desired morphology of the microdomains that are to be formed by the self-assembly process, and the volumes of the blocks are next determined based on the desired size and spacing of the microdomains. The blocks are then deposited onto the surface of a substrate as a thin film. The blocks have the volume and volume ratio that provide the desired morphology, size and spacing.

An annealing process is then performed to cause the diblock copolymers to self-assemble. The microdomains and matrix into which the diblock copolymers self-assemble dictate the size and distribution (e.g., relative spacing) of the inorganic structural elements that will later be formed from the carried inorganic payloads. Further, this self-assembly technique provides a high yield as substantially all of the inorganic structural elements formed by the self-assembled diblock copolymers remain on the substrate after an oxidation process (e.g., UV-ozone or oxygen plasma) treatment is performed to remove the organic component of the diblock copolymer, as will be described further below. The oxidation process additionally oxidizes the inorganic species to form a non-volatile inorganic oxide. The inorganic oxide forms structural elements that collectively constitute a mask having nanometer-scale features. The mask having nanometer-scale features is used in an etch process that defines nanometer-scale structures in a substrate.

In accordance with an embodiment of the invention, the mask having nanometer-scale features is formed over a substrate. The mask is used in an etch process that defines nanometer-scale structures in the substrate.

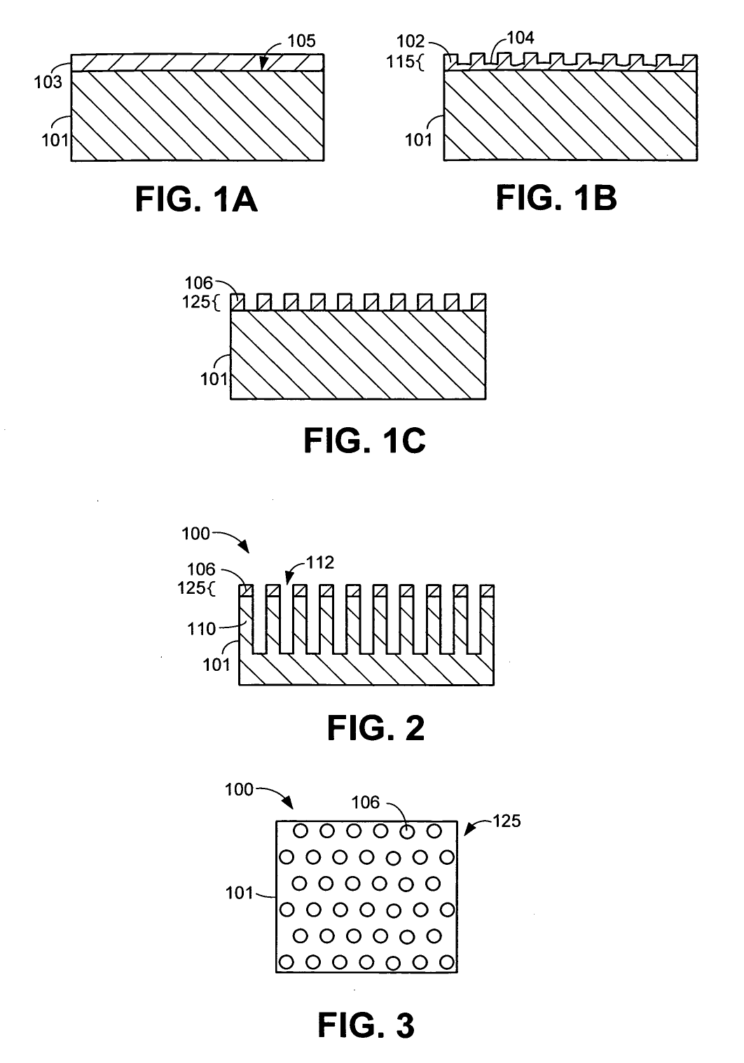

FIGS. 1A through 1C are schematic cross-sectional views showing various stages of an embodiment of a process for forming a nanometer-scale mask in accordance with an embodiment of the invention. FIG. 1A shows a vector polymer film 103 deposited on the surface 105 of a substrate 101. The substrate 101 comprises silicon, quartz, or another suitable substrate material. In one example, the substrate 101 can be part of a separation structure for a chromatograph or another molecular analysis device in which it is desired to form one or more nanometer-scale structures. For a separation structure, the substrate 101 is typically silicon. The vector polymer film 103 is deposited on the surface 105 of the substrate 101 by, for example, spin coating, dip coating, or another application process known in the art. The vector polymer film 103 is approximately 50-100 nanometers (nm) thick. Examples of materials that can be used to form the vector polymer film 103 include polystyrene-b-polydimethylsiloxane (PS-PDMS), polyisoprene-b-polydimethylsiloxane (PI-PDMS), polyisoprene-b-polyferrocenylmethylethylsilane (PI-PFEMS), polystyrene-b-polyferrocenylmethylethylsilane (PS-PFEMS), polystyrene-b-polyvinylmethylsiloxane (PS-PVMS), polystyrene-b-polybutadiene (PS-PB), where the polybutadiene (PB) is stained by osmium tetroxide (OsO₄), and polystyrene-b-polyvinylpridine (PS-PVP), where the pyridine group forms a coordination bond with an inorganic species. Other materials that can form a block copolymer can additionally or alternatively be used.

FIG. 1B shows the substrate 101 and the vector polymer film 103 shown in FIG. 1A after the vector polymer film 103 has been annealed. Annealing the vector polymer film 103 causes the vector polymer film 103 to self-assemble into a block copolymer 115 having a nanometer-scale morphology defined by the volume ratio of the two blocks constituting the block copolymer 115. In the example shown, the volume ratio of the blocks that form the block copolymer 115 is such that the block copolymer 115 self-assembles with a cylindrical morphology.

In the example shown in FIG. 1B, self-assembly of the block copolymer 115 results in a periodic array of microdomains embedded in a matrix. An exemplary one of the microdomains is illustrated at 102 and an exemplary part of the matrix is illustrated at 104. In an embodiment, the block copolymer 115 is formed using polystyrene-b-polyferrocenylmethylethylsilane (PS-PFEMS), where the material of the matrix 104 is polystyrene (PS) and the material of the microdomain 102 is polyferrocenylmethylethylsilane (PFEMS). In this example, the microdomain 102 comprises organic material and inorganic species. The inorganic species are silicon and iron that form respective non-volatile oxides. The matrix 104 consists only of organic material. In other examples, the material of the microdomain 102 consists of only one organic species.

FIG. 1C shows the substrate 101 and the block copolymer 115 shown in FIG. 1B after the block copolymer 115 has been subject to oxidation. The block copolymer 115 is oxidized using, for example, oxygen (O₂) plasma etching or ultraviolet (UV)-ozonation, as known in the art. The oxidation process removes the organic components of the block copolymer 115 and converts each inorganic species of the block copolymer 115 into a respective inorganic oxide. Specifically, the oxidation process removes the organic matrix 104 shown in FIG. 1B and the organic component of the microdomains 102. The oxidation process additionally converts the inorganic species in the microdomains 102 to respective inorganic oxides that form posts 106. As can be seen in FIG. 3, the posts 106 are periodically arrayed on the surface 105 (FIG. 1A) of the substrate 101 in the same arrangement as the microdomains 102 described above with reference to FIG. 1B. The posts 106 are structural elements that collectively constitute a mask 125 having nanometer-scale features. Using current processing technology, the array of posts 106 has a pitch of approximately 20 nanometers to approximately 100 nanometers and the posts 106 are approximately 5 nanometers to approximately 50 nanometers in diameter.

FIG. 2 is a schematic diagram showing a process for using the mask 125 of FIG. 1C to define a nanometer-scale structure in a substrate.

An etchant is introduced to etch the material of the substrate 101 in areas that are unprotected by the mask 125. In this example, the etchant used to etch the substrate 101 is a halide gas as known in the art. A halide etchant can use, for example, fluoride, chloride or bromide gas or a mixture of these gases. The etchant used to etch the substrate 101 also partially etches the posts 106 of the mask 125. However, the etch process is stopped in sufficient time to prevent the posts 106 from being completely removed by the etchant. In this example, the etch process defines a periodic array of pillars 110 in the substrate 101. The pitch of the array of pillars is defined by the periodic morphology of the mask 125. In this example, the pitch of the array of pillars 110 is on the order of 20 to 150 nanometers. The etch process is designed to define channels 112 that are, in this example, approximately 200 nanometers deep. However, other depths are possible.

When implemented in a three-dimensional structure as a separation structure (also referred to as separation medium) for a chromatograph or for electrophoresis, the pillars 110 and the channels 112 form the structure of a separation medium. The pillars 110 can be chemically treated to reduce nonspecific interactions with molecules in the solution passing the pillars 110 and to obtain sufficient retention characteristics. Molecules such as DNA, RNA, peptides, proteins, synthetic analogs of nucleic acids, complexes of different biomolecules etc., in a fluid solution can be separated by molecular size and structure as they flow past and through the pillars 110 and the channels 112. Such an application will be discussed below. Further, the separation structure formed by the pillars 110 can be cleaned and reused.

FIG. 3 is a schematic diagram illustrating a plan view of the mask 125 shown in FIG. 1C. The mask 125 is composed of nanometer-scale structural elements periodically arrayed on the surface 105 (FIG. 1A) of the substrate 101. In the example shown, the posts 106 constitute the structural elements of the mask 125. The shape and size of the structural elements and the way in which the structural elements are arrayed are defined by the structure of the block copolymer 115 (FIG. 1B). In the example shown, the posts 106 are cylindrical and are disposed with their circular cross section parallel to the plane of the surface 105 (FIG. 1A) of the substrate 101. However, the above-described process can be used to form the structural elements of the mask 125 with a shape different from that of the cylindrical posts 106.

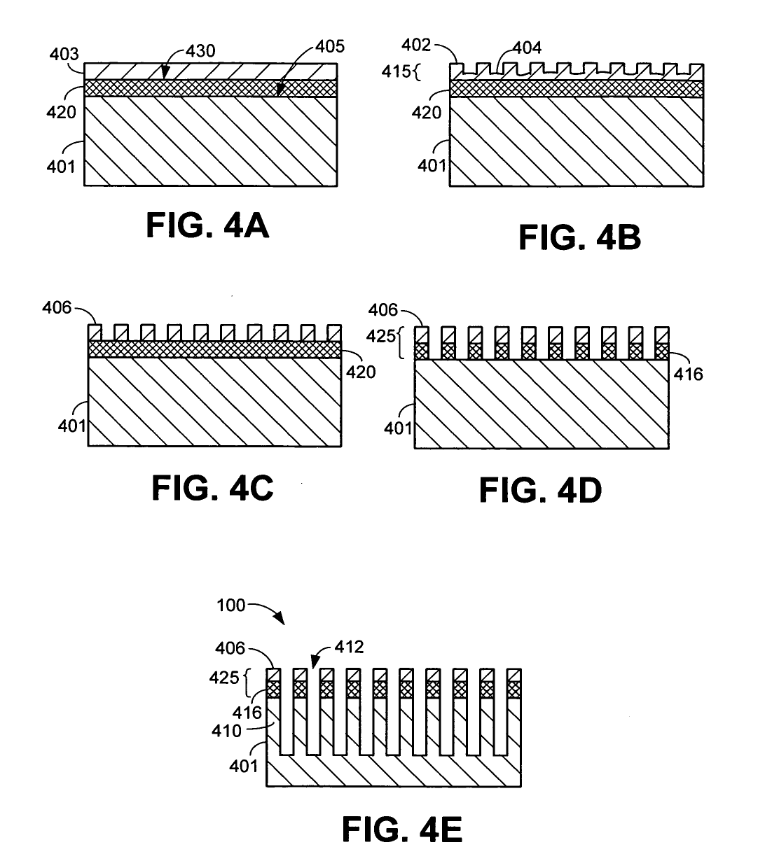

FIGS. 4A through 4E are schematic diagrams showing an alternative embodiment of a process for creating a mask using the self-assembled block copolymer of FIGS. 1A through 1C and using the mask to etch a substrate.

The process illustrated in FIGS. 4A through 4E is similar to that illustrated in FIGS. 1A through 1C and FIG. 2, except that a hard mask layer is applied over the surface of the substrate prior to depositing the vector polymer film. FIG. 4A shows a hard mask layer 420 applied over the surface 405 of the substrate 401. The substrate 401 is similar to the substrate 101 of FIG. 1A. In this example, the hard mask layer 420 is a layer of tantalum approximately 20 nanometers thick. The hard mask layer 420 has superior etch resistance to the halide gas used to etch the silicon substrate. A halide etchant can use, for example, fluoride, chloride or bromide gas or a mixture of these gases. A vector polymer film 403 is deposited on the surface 430 of the hard mask layer 420, as described above.

FIG. 4B shows the substrate 401, hard mask 420 and the vector polymer film 403 shown in FIG. 4A after the vector polymer film 403 has been annealed. Annealing the vector polymer film 403 causes the vector polymer film 403 to self-assemble into a block copolymer 415 having a nanometer-scale morphology defined by the volume ratio of the two blocks constituting the block copolymer 415. In the example shown, the volume ratio of the blocks that form the block copolymer 415 is such that the block copolymer 415 self-assembles with a cylindrical morphology. The block-copolymer 415 is similar to the block-copolymer 115 described above and includes microdomains 402 and matrix 404.

FIG. 4C shows the posts 406 remaining after the block copolymer 415 has been subject to oxidation, as described above. The posts 406 define a periodic array of structural elements over the hard mask layer 420. The oxidation process removes the organic components of the block copolymer 415 and converts each inorganic species of the block copolymer 415 into a respective inorganic oxide. Specifically, the oxidation process removes the organic matrix 404 shown in FIG. 4B and the organic component of the microdomains 402. The oxidation process additionally converts the inorganic species in the microdomains 402 to respective inorganic oxides that form posts 406. The posts 406 are periodically arrayed on the surface 430 (FIG. 4A) of the hard mask 403 in the same arrangement as the microdomains 402 described above with reference to FIG. 4B.

FIG. 4D shows the substrate 401, hard mask 420 and the posts 406 of FIG. 4C after portions of the hard mask layer 420 exposed after removal of the matrix 404 have been subject to a removal process such as ion milling using, for example, argon ions as known in the art.

Ion milling is an example of a process that can be used to remove the portions of the hard mask layer 420 that are exposed by the removal of the matrix 404, leaving the posts 416 below the posts 406. The posts 406 and the posts 416 form a pattern of nanometer-scale structures. The posts 406 and the posts 416 are structural elements that collectively constitute a mask 425. Using current processing technology, the array of posts 406 has a pitch of approximately 20 nanometers to approximately 100 nanometers and the posts 306 are approximately 5 nanometers to approximately 50 nanometers in diameter. The posts 416 conform to the shape and arrangement of the posts 406.

FIG. 4E shows the mask 425 used in a process in which the substrate 401 is etched as described above. An etchant is introduced to etch the material of the substrate 401 in areas that are unprotected by the mask 425. In this example, the etchant used to etch the substrate 401 is a halide gas as known in the art. A halide etchant can use, for example, fluoride, chloride or bromide gas or a mixture of these gases. The posts 416 constituting the mask 425 remain even if the halide gas etchant completely removes the posts 406. In this example, the etch process defines pillars 410 in the substrate 401. The pitch of the pillars is defined by the periodic morphology of the mask 425. In this example, the pitch of the pillars 410 is on the order of 20 to 150 nanometers. The etch process is designed to define channels 412 that are, in this example, approximately 200 nanometers deep. However, other depths are possible. The structure shown in FIG. 4E can be used in a biomolecule separation structure as described above.

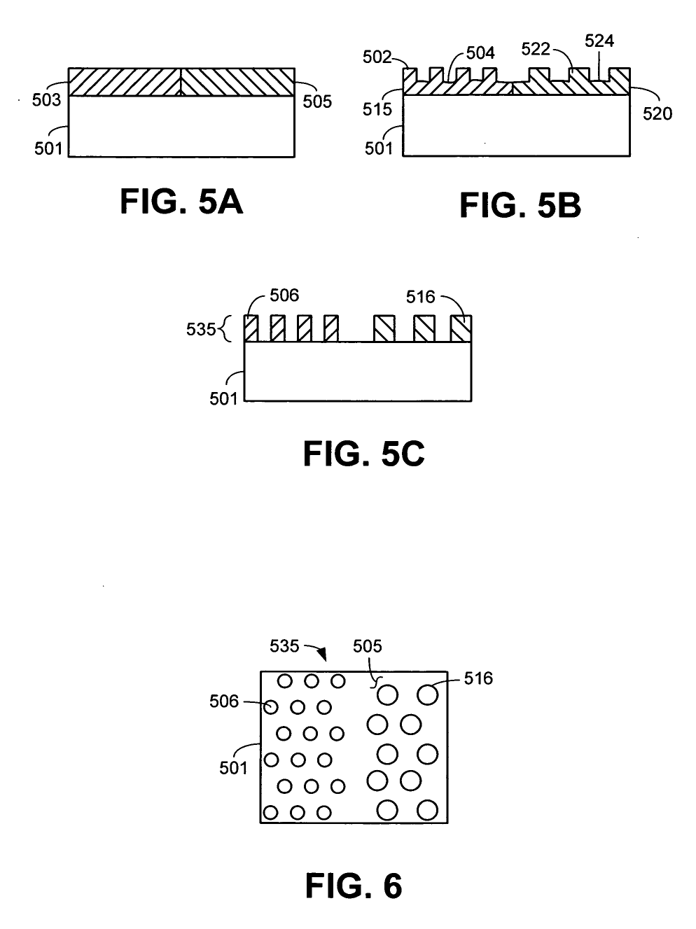

FIG. 5A is a schematic diagram showing a profile view of two vector polymer films applied to respective regions of the surface of a substrate. FIG. 5A shows a vector polymer film 503 deposited on one region of the surface of a substrate 501 and a vector polymer film 505 deposited on another region of the surface of the substrate 501. To deposit the vector polymer films 503 and 505 in their respective regions of the surface of the substrate 501, substrate 501 could be dip coated from one end into a solution that forms the vector polymer film 503 and then dip coated from the opposite end into the solution that forms the vector polymer film 505, resulting in the vector polymer film 503 being juxtaposed with the vector polymer film 505. Alternatively, a photolithographic mask can be used to mask one portion of the surface of substrate 501. The unprotected portion is coated with the vector polymer film 503 or the vector polymer film 505. The process is then repeated on the uncoated portion of the surface of substrate 501 with the other vector polymer film. The ratio of the components that form the vector polymer films 503 and 505 are chosen to result in a cylindrical morphology. However, other morphologies are possible.

FIG. 5B is a schematic diagram showing a profile view of the vector polymer films applied to respective regions of the surface of a substrate 501 after annealing. As described above, annealing the vector polymer films 503 and 505 causes the vector polymer film 503 to self-assemble into block copolymer 515 and causes the vector polymer film 505 to self-assemble into block copolymer 520. The two block copolymers 515 and 520 have mutually different morphologies. The different morphologies result in the block copolymer 515 having microdomains that differ in lateral dimension and pitch from the microdomains of block copolymer 520. The block copolymer 515 comprises microdomains 502 and matrix 504. The block copolymer 520 comprises microdomains 522 and matrix 524. The microdomains 522 have a lateral dimension that is different than the lateral dimension of the microdomains 502.

FIG. 5C shows the block copolymers 515 and 520 of FIG. 5A after oxidation. As described above, to form a mask 535 with nanometer-scale features, the block copolymers 515 and 520 are oxidized to remove the matrix portions 504 and 524, and to convert the microdomains 502 and 522 into inorganic oxide material that forms the structural elements of the mask 535. The oxidation process converts the inorganic species in the microdomains 502 to respective inorganic oxides that form posts 506 and converts the inorganic species in the microdomains 522 to respective inorganic oxides that form posts 516. The posts 506 and 516 form the mask 535.

FIG. 6 is a schematic diagram showing a plan view of the mask 535 of FIG. 5C. The surface 505 of the substrate 501 comprises a pattern of posts 506 and posts 516. However, the different block copolymers 515 and 520 create regions of nanoscale structures having different proportions. The different nanoscale structures form a mask 535 that can be used as described above in a process in which the material of the substrate 501 is etched as described above. When implemented in a molecule separation application, the differences in lateral dimension and pitch of the posts 506 and 516, allow the mask 535 to be used to define in substrate 501 nanometer-scale structures of differing dimensions that can be used to perform multiple size separation of molecules. The mask 535 can also be used with the underlying hard mask layer as described in FIGS. 4A through 4E.

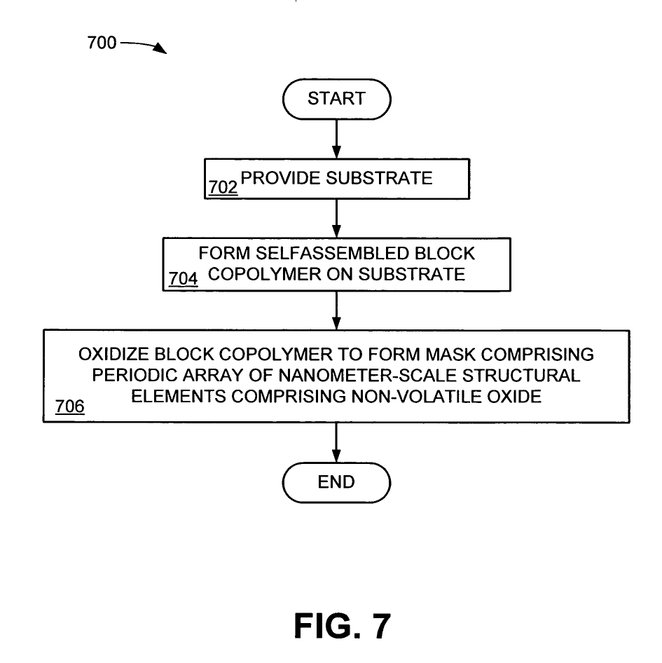

FIG. 7 is a flowchart showing a method of forming a nanometer-scale mask in accordance with an embodiment of the invention. In block 702, a substrate is provided. In block 704, a self-assembled block copolymer is formed on the substrate. The block copolymer comprises a matrix and a periodic array of microdomains embedded in the matrix. The microdomains comprise an inorganic species having a non-volatile oxide. In an embodiment, the microdomains of the block copolymer exhibit a cylindrical morphology. Other morphologies are possible. In block 706, the self-assembled block copolymer is oxidized to form a periodic array of nanometer-scale structural elements comprising the non-volatile oxide. The oxidation process removes the organic component of the block copolymer and converts the inorganic component of the block copolymer in each microdomain into a respective nanometer-scale structure comprising the non-volatile inorganic oxide. In an embodiment, the nanometer-scale structures are cylindrical in shape, depending on the shape of the microdomain from which they were formed. The nanometer-scale structure forms a mask.

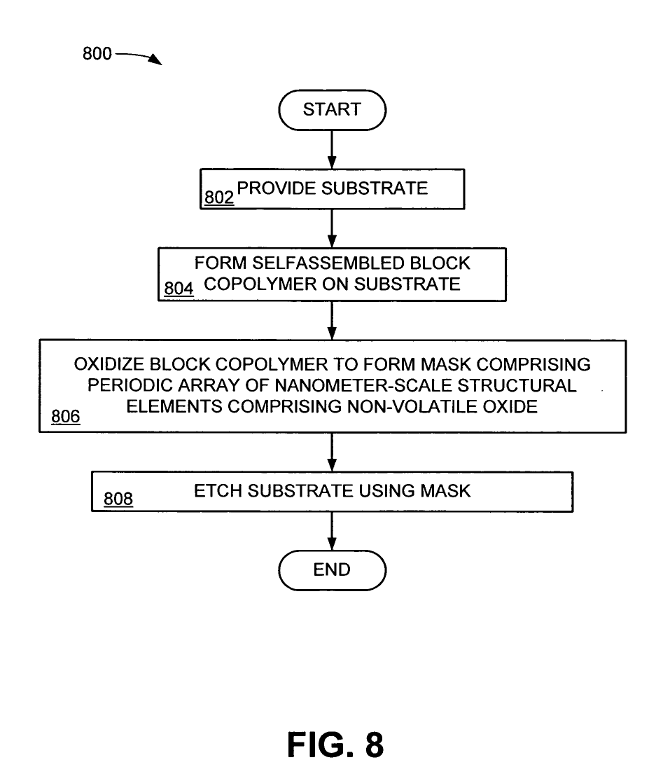

FIG. 8 is a flowchart 800 showing a method of defining a nanometer-scale structure in accordance with an embodiment of the invention. In block 802, a substrate is provided. In block 804, a self-assembled block copolymer is formed on the substrate. The block copolymer comprises a matrix and a periodic array of microdomains embedded in the matrix. The microdomains comprise an inorganic species having a non-volatile oxide. In an embodiment, the microdomains of the block copolymer exhibit a cylindrical morphology. Other morphologies are possible. In block 806, the self-assembled block copolymer is oxidized to form a periodic array of nanometer-scale structural elements comprising the non-volatile oxide. The oxidation process removes the organic component of the block copolymer and converts the inorganic component of the block copolymer in each microdomain into a respective nanometer-scale structure comprising the non-volatile inorganic oxide. In an embodiment, the nanometer-scale structures are cylindrical in shape, depending on the shape of the microdomain from which they were formed. The nanometer-scale structure forms a mask. In block 808, the mask is used in an etch process performed on the substrate to define one or more nanometer-scale structures in the substrate.

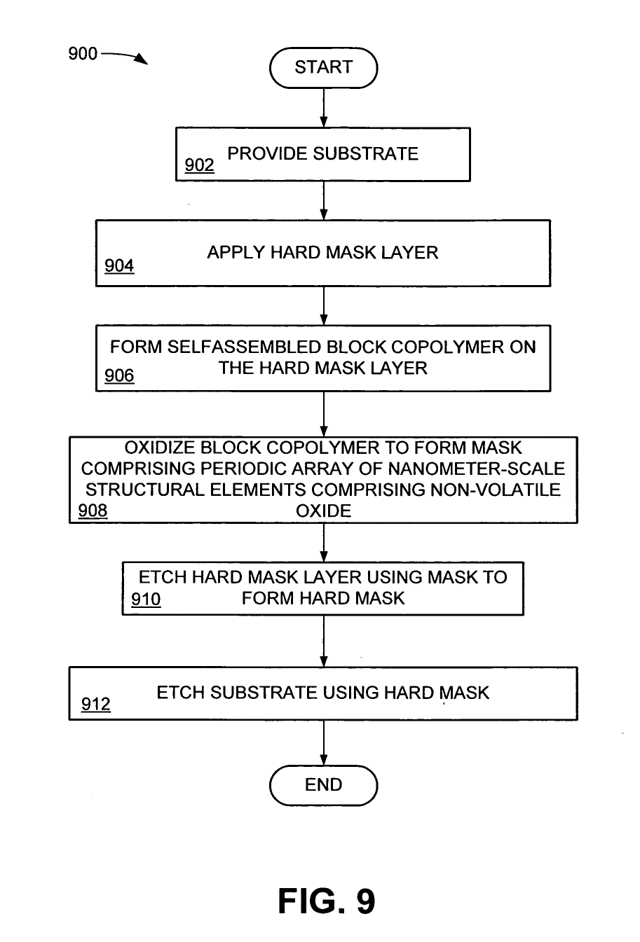

FIG. 9 is a flowchart 900 showing an alternative method of defining a nanometer-scale structure in accordance with another embodiment of the invention. In block 902, a substrate is provided. In block 904, a hard mask layer is applied to the surface of the substrate. In an embodiment, the hard mask layer is approximately 20 nanometers thick. The material of the hard mask can be, for example, tantalum, or another hard mask material. In block 906, a self-assembled block copolymer is formed on the hard mask layer, as described above. In block 908, the self-assembled block copolymer is oxidized to form a periodic array of nanometer-scale structural elements comprising a non-volatile oxide. The oxidation process removes the organic component of the block copolymer and converts the inorganic component of the block copolymer in each microdomain into a respective nanometer-scale structure comprising the non-volatile inorganic oxide, as described above. In block 910, the portions of the hard mask that are exposed by the removal of the matrix are etched using, for example, a halide etch process. The non-volatile inorganic oxide and the hard mask material beneath the non-volatile inorganic oxide form a mask. In block 912, the mask is used in an etch process performed on the substrate to define one or more nanometer-scale structures in the substrate.

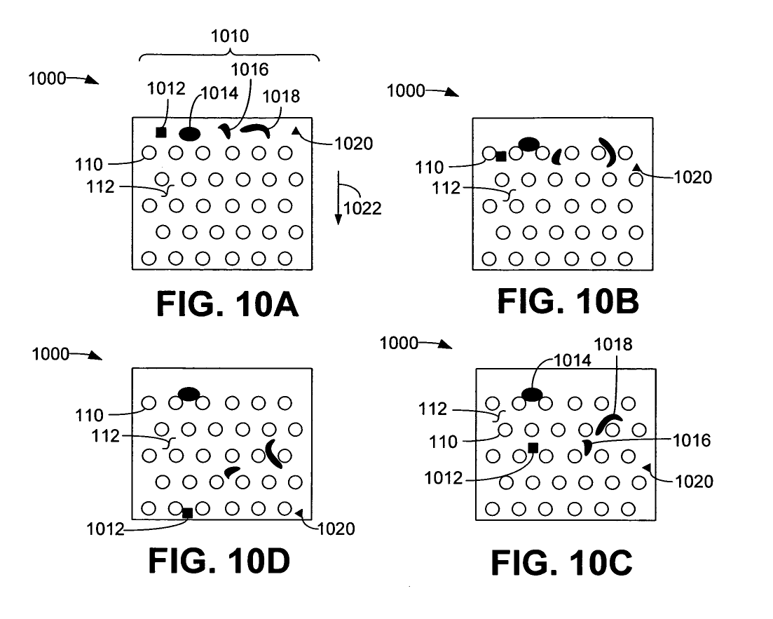

FIGS. 10A through 10D are schematic diagrams showing plan views of a biomolecule separation medium 1000 created using the block copolymer mask described above. In FIG. 10A, the separation medium 1000 comprises posts 110 and channels 112, as described in FIG. 3. Biomolecules or biomolecular complexes, which are collectively referred to as biomolecular material, are illustrated collectively using reference numeral 1010 and are referred to individually as biomolecules 1012, 1014, 1016, 1018 and 1020. The biomolecular material 1010 can be any biomolecules or biomolecular complexes that are sought to be separated by physical size. In addition, the physical flexibility of a biomolecule, the solution in which the biomolecule is carried, the temperature of the environment, and whether an electrical potential is applied to the separation medium 1000 will also influence the speed at which a biomolecule will travel through the separation medium 1000. In this manner, the biomolecular material 1010 can be separated based on physical size, conformation and conformational flexibility. Conformation refers to the shape of a biomolecule due to its molecular content and structure. A conformationally flexible biomolecule is capable of changing shape with minimal energy loss.

The biomolecular material 1010 can be denatured or non-denatured. The biomolecular material 1010 can be part of biomolecule complexes that can be analyzed as a complex or divided and analyzed individually. For example, a biomolecule complex can be divided into individual biomolecules at different stages of a multiple-stage separation medium by varying the conditions of the solution in which the biomolecule complex is carried through the separation medium 1000. The direction of flow of the biomolecular material 1010 through the separation medium 1000 is illustrated using arrow 1022, but is arbitrary.

In FIG. 10B, the biomolecular material 1010 has begun moving through the separation medium 1000. The pitch and diameter of the posts 110 creates a physical barrier to the individual biomolecules in the biomolecular material 1010 and as a result, different size biomolecules will move through the separation medium 1000 at different speeds. As shown in FIG. 10B, the biomolecule 1020 has progressed farther through the separation medium 1000 than the other biomolecules.

In FIG. 10C, the biomolecules in the biomolecular material 1010 have progressed through the separation medium 1000 at different rates. In FIG. 10D, the biomolecules 1012 and 1020 have progressed completely through the separation medium 1000 and, if additional analysis desired, can be directed to another separation medium having characteristics different than the characteristics of the separation medium 1000. In this manner, biomolecules can be separated based on physical size.

The separation medium 1000 can be re-usable. The level of nanoscale control in the construction of a molecular measuring device, such as the separation medium 1000, is expected to provide consistently reproducible structures. Since the structure and dimensions of the separation medium 1000 are definable and controllable at the nanometer-scale, the separation medium provides consistent results in performing biomolecular separations.

The separation medium 1000 can be used to separate biomolecules such as DNA, RNA, proteins, and synthetic analogs of nucleic acids or proteins. The separation can be based on the molecular size or structure or a combination of size and structure.

Separation media containing different channel and structure sizes, as described above, can be connected to perform serial size separation of a complex biomolecular mixture.

In addition, the separation medium 1000 can be used in conjunction with liquid chromatography for size or structure separation of biomolecules.

This disclosure describes the invention in detail using illustrative embodiments. However, it is to be understood that the invention defined by the appended claims is not limited to the precise embodiments described.

What is claimed is:

1. A nanometer-scale mask, comprising a periodic array of nanometer-scale structural elements comprising an inorganic oxide.

2. The mask of claim 1, in which the inorganic oxide constituting the structural elements comprises an inorganic species remaining after oxidation of a self-assembled block copolymer, the self-assembled block copolymer comprising a matrix and a periodic array of microdomains embedded in the matrix, the microdomains comprising the inorganic species.

3. The mask of claim 1, in which the matrix comprises one of polystyrene (PS) and polyisoprene (PI).

4. The mask of claim 1, in which the microdomains comprise one of polydimethylsiloxane (PDMS), polyferrocenylmethylethylsilane (PFEMS), polyvinyl-ethylphenolsilane (PFPMS) polyvinylmethylsiloxane (PVMS), polybutadiene (PB), where the polybutadiene (PB) is stained by OsO₄, and polyvinylpridine (PVP), where the pyridine group forms a coordination bond with the inorganic species.

5. The mask of claim 1, further comprising an additional periodic array of nanometer-scale structural elements having features that differ dimensionally from the features of the periodic array.

6. The mask of claim 1, further comprising a hard mask material.

7. The mask of claim 6, in which the hard mask material is patterned in accordance with the periodic array of nanometer-scale structural elements.

8. The mask of claim 7, in which the hard mask material comprises tantalum.

9. A method for forming a mask on a substrate, comprising:
forming a self-assembled block copolymer on the substrate, the self-assembled block copolymer comprising a matrix and a periodic array of microdomains embedded in the matrix, the microdomains comprising an inorganic species having a non-volatile oxide; and
oxidizing the self-assembled block copolymer to form as the mask a periodic array of nanometer-scale structural elements comprising the non-volatile oxide.

10. The method of claim 9, in which:
the forming comprises depositing a vector polymer on the substrate and annealing the vector polymer; and
the method further comprises etching a nanometer-scale structure into the substrate using the mask.

11. The method of claim 9, further comprising forming a hard mask over the substrate prior to forming the self-assembled block copolymer.

12. The method of claim 9, in which the forming comprises depositing a vector polymer film on the substrate.

13. The method of claim 9, in which the matrix of the self-assembled block copolymer comprises one of polystyrene (PS) and polyisoprene (PI).

14. The method of claim 9, in which the microdomains comprise one of polydimethylsiloxane (PDMS), polyferrocenylmethylethylsilane (PFEMS), polyvinyl-ethylphenolsilane (PFPMS) polyvinylmethylsiloxane (PVMS), polybutadiene (PB), where the polybutadiene (PB) is stained by OsO₄, and polyvinylpridine (PVP), where the pyridine group forms a coordination bond with the inorganic species.

15. The method of claim 9, further comprising:
forming an additional self-assembled block copolymer on the substrate, the additional self-assembled block copolymer comprising a matrix and a periodic array of microdomains embedded in the matrix, the microdomains comprising an inorganic species having a non-volatile oxide; and
where the oxidizing comprises oxidizing the additional self-assembled block copolymer to form an additional periodic array of nanometer-scale structural elements comprising the non-volatile oxide, wherein the additional periodic array forms an additional mask having features that differ dimensionally from the features in the mask.

16. A method for forming a nanometer-scale biomolecule separation structure, comprising:
providing a substrate;
forming a self-assembled block copolymer on the substrate, the self-assembled block copolymer comprising a matrix and a periodic array of microdomains embedded in the matrix, the microdomains comprising an inorganic species having a non-volatile oxide;
oxidizing the self-assembled block copolymer to form a periodic array of nanometer-scale structural elements comprising the non-volatile oxide, wherein the periodic array forms a mask; and
etching a nanometer-scale structure in the substrate using the mask to define in the substrate the nanometer-scale structure providing the biomolecule separation structure.

17. The method of claim 16, in which the forming comprises depositing a vector polymer film on the substrate.

18. The method of claim 16, in which the matrix of the self-assembled block copolymer comprises one of polystyrene (PS) and polyisoprene (PI).

19. The method of claim 16, in which the microdomains comprise one of polydimethylsiloxane (PDMS), polyferrocenylmethylethylsilane (PFEMS), polyvinyl-ethylphenolsilane (PFPMS) polyvinylmethylsiloxane (PVMS), polybutadiene (PB), where the polybutadiene (PB) is stained by OsO₄, and polyvinylpridine (PVP), where the pyridine group forms a coordination bond with the inorganic species.

20. The method of claim 16, in which the method additionally comprises using the biomolecule separation structure to separate biomolecules chosen from DNA, RNA, proteins, synthetic analogs of nucleic acids or proteins, complexes of DNA, RNA, proteins and synthetic analogs of nucleic acids or proteins based on at least one of molecular size and structure.

21. The method of claim 16, additionally comprising using the nanometer-scale biomolecule separation structure in conjunction with liquid chromatography.

22. The method of claim 16, further comprising:
forming an additional self-assembled block copolymer on the substrate, the additional self-assembled block copolymer comprising a matrix and a periodic array of microdomains embedded in the matrix, the microdomains comprising an inorganic species having a non-volatile oxide; and
where the oxidizing comprises oxidizing the additional self-assembled block copolymer to form an additional periodic array of nanometer-scale structural elements comprising the non-volatile oxide, wherein the additional periodic array forms an additional mask having features that differ dimensionally from the features in the mask.

23. The method of claim 22, further comprising performing serial size separation of a complex biomolecular mixture using the nanometer-scale biomolecule separation structure.

24. A method for defining a nanometer-scale structure in a substrate, comprising:
providing a substrate;
forming a self-assembled block copolymer on the substrate, the self-assembled block copolymer comprising a matrix and a periodic array of microdomains embedded in the matrix, the microdomains comprising an inorganic species having a non-volatile oxide;
oxidizing the self-assembled block copolymer to form a periodic array of nanometer-scale structural elements comprising the non-volatile oxide, wherein the periodic array forms a mask; and
etching a nanometer-scale structure in the substrate using the mask to define the nanometer-scale structure.
